(19) United States
(12) Patent Application Publication
(10) Pub. No.: US 2019/0029114 A1
(43) Pub. Date: Jan. 24, 2019

(54) WIRING BOARD AND PLANAR TRANSFORMER

(71) Applicant: NGK SPARK PLUG CO., LTD., Nagoya-shi (JP)

(72) Inventor: Masahito Morita, Yokohama-shi (JP)

(21) Appl. No.: 16/037,031

(22) Filed: Jul. 17, 2018

(30) Foreign Application Priority Data
Jul. 21, 2017 (JP) 2017-142018

(51) Int. Cl. H05K 1/16; H05K 1/11; H01F 27/28; H05K 3/00; H05K 1/03; H05K 3/40; H01F 41/04

(52) U.S. Cl. CPC H05K 1/165; H05K 1/115; H01F 27/2804; H05K 3/0014; H05K 1/0306; H05K 1/0271; H01F 41/043; H05K 2201/0195; H01F 2027/2819; H05K 2201/068; H05K 3/4061

(57) ABSTRACT

A wiring board includes at least one insulating layer that has a front surface and a back surface, a first wiring layer that is disposed on a front surface side of the at least one insulating layer, a second wiring layer that is disposed on a back surface side of the insulating layer where the first wiring layer is disposed, and a connection conductor that electrically connects the first wiring layer and the second wiring layer to each other. Of the first wiring layer and the second wiring layer, at least the first wiring layer includes an unfixing region that is not fixed to the insulating layer.

### CROSS REFERENCE TO RELATED APPLICATION

The present application claims priority to Japanese Patent Application No. 2017-142018, which was filed on Jul. 21, 2017, the disclosure of which is herein incorporated by reference in its entirety.

### BACKGROUND OF THE INVENTION

### 1. Field of the Invention

The present disclosure relates to a wiring board and a planar transformer.

### 2. Description of the Related Art

As a method of manufacturing a wiring board including a plurality of insulating layers and a plurality of wiring layers that are alternately laminated to each other, a method of forming the wiring layers by performing printing on the insulating layers using a metal paste, and then by firing is known. However, in this method, since a wiring section cannot be made sufficiently thick, there is a limit to how much the resistance of the wiring section can be reduced.

On the other hand, a method of forming a wiring layer by adhering a metal foil to an insulating layer is also known (refer to PTL 1).

### RELATED ART DOCUMENT

PTL 1 is Japanese Unexamined Patent Application Publication No. 11-329842.

As described above, in a wiring board in which a wiring layer is joined to an insulating layer, when a joining area between the wiring layer and the insulating layer is increased, stress due to changes in temperature caused by differences between the thermal expansion coefficient of the insulating layer and the thermal expansion coefficient of the wiring layer is generated. Therefore, defects, such as cracks or breakages, tend to occur in a portion of the insulating layer that is joined to the wiring layer; and the wiring layer tends to peel off.

### BRIEF SUMMARY OF THE INVENTION

An object of an aspect of the present disclosure is to provide a wiring board that makes it possible to suppress the occurrence of defects in an insulating layer where a wiring layer is disposed.

According to a form of the present disclosure, there is provided a wiring board including at least one insulating layer that has a front surface and a back surface, a first wiring layer that is disposed on (adjacent to) a front surface side of the at least one insulating layer, a second wiring layer that is disposed on (adjacent to) a back surface side of the insulating layer where the first wiring layer is disposed, and a connection conductor that electrically connects the first wiring layer and the second wiring layer to each other. At least the first wiring layer includes an unfixing region that is not fixed to the insulating layer of the first wiring layer and the second wiring layer.

According to such a structure, when the first wiring layer and the insulating layer have expanded or contracted due to changes in temperature, differences between the deformation amount of the first wiring layer and the deformation amount of the insulating layer caused by differences between the thermal expansion coefficient of the first wiring layer and the thermal expansion coefficient of the insulating layer can be absorbed by the unfixing region that is not fixed to the insulating layer. Therefore, stress that is generated between the insulating layer and the first wiring layer is reduced, and defects, such as cracks or breakages, in the insulating layer are suppressed.

In the form of the present disclosure, the first wiring layer may include at least one fixing region that is fixed to the insulating layer, and the at least one fixing region may include a connection-portion fixing region that is fixed to the insulating layer by the connection conductor. According to such a structure, since the second wiring layer can be fixed to the insulating layer with a relatively small area via the connection conductor, it is possible to hold the wiring layer with respect to the insulating layer while suppressing the generation of stress caused by differences between the thermal expansion coefficients.

In the form of the present disclosure, the at least one fixing region further may include an auxiliary fixing region where the first wiring layer is fixed to the insulating layer at a location other than the connection-portion fixing region. According to such a structure, it is possible to more stably hold the wiring layer while suppressing the generation of stress caused by differences between the thermal expansion coefficients.

In the form of the present disclosure, a maximum distance from a gravity center of the at least one fixing region to an outer edge of the at least one fixing region as viewed from a thickness direction of the first wiring layer may be 7 mm or less. According to such a structure, it is possible to reliably suppress the occurrence of defects in the insulating laver.

In the form of the present disclosure, the insulating layer may include a grooved portion that is thinner than other portions, and at least a part of the first wiring layer in a thickness direction may be disposed in the grooved portion. According to such a structure, it is possible to reduce the thickness of the wiring board while suppressing the generation of stress caused by differences between the thermal expansion coefficient of the insulating layer and the thermal expansion coefficient of the wiring laver.

In the form of the present disclosure, the insulating layer may have a through hole that extends through the insulating layer in a thickness direction, and the connection conductor may be disposed in the through hole. According to such a structure, in the wiring board using a so-called via, it is possible to suppress the occurrence of defects in the insulating layer.

In the form of the present disclosure, at least one wiring layer of the first wiring layer and the second wiring layer has an auxiliary through hole at a location overlapping the through hole In other words, at least one of the first wiring layer and the second wiring layer defines an auxiliary through hole at a location overlapping the through hole of the at least one insulating layer. According to such a structure, gas that is generated when forming the connection conductor can be discharged to the outside of the through hole of the insulating layer. As a result, it is possible to suppress bulging of the wiring layer occurring when joining the insulating layer.

In the form of the present disclosure, the at least one insulating layer may include a first insulating layer and a second insulating layer, the first wiring layer being disposed on a front surface side of the first insulating layer and the second wiring layer being disposed on a back surface side of the first insulating layer, the second insulating layer being disposed on the front surface side of the first insulating layer with the first wiring layer interposed between the front surface side of the first insulating layer and the second insulating layer. The wiring board may further include an insulating layer fixing member that fixes the first insulating layer and the second insulating layer to each other in a thickness direction. The insulating layer fixing member may be disposed so as to surround the first wiring layer as viewed from the thickness direction of the first insulating layer. According to such a structure, the wiring layer is sealed by the insulating layer fixing member and the insulating layer, and oxidation of the wiring layer and short circuits between wires caused by moisture in the air are suppressed. As a result, it is possible to increase the reliability of the wiring board.

### BRIEF DESCRIPTION OF THE DRAWINGS

Illustrative aspects of the invention will be described in detail with reference to the following figures wherein:

FIG. 1 is a schematic sectional view of a wiring board of an embodiment.

FIG. 2A is a schematic partial enlarged sectional view of the vicinity of connection conductors in the wiring board in FIG. 1; and FIG. 2B is a schematic sectional view along line IIB-IIB of FIG. 2A.

FIG. 3A is a schematic sectional view of a wiring board of an embodiment differing from that shown in FIG. 1; and FIG. 3B is a schematic sectional view of a wiring board of an embodiment differing from those shown in FIGS. 1 and 3A.

FIG. 4 is a schematic sectional view of a wiring board of an embodiment differing from those shown in FIGS. 1, 3A, and 3B.

FIG. 5 is a schematic sectional view of a wiring board of an embodiment differing from those shown in FIGS. 1, 3A, 3B, and 4.

FIG. 6 is a schematic sectional view of a wiring board of an embodiment differing from those shown in FIGS. 1, 3A, 3B, 4, and 5.

### DETAILED DESCRIPTION OF THE EXEMPLARY EMBODIMENTS OF THE INVENTION

Embodiments to which the present disclosure is applied are described below by using the drawings.

1. First Embodiment

1-1. Wiring Board

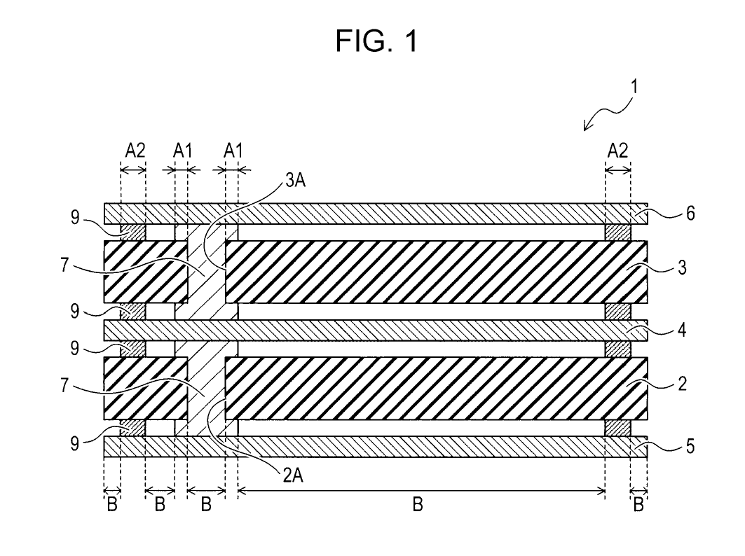

A wiring board 1 shown in FIG. 1 includes a plurality of insulating layers (a first insulating layer 2 and a second insulating layer 3), a plurality of wiring layers (a first wiring layer 4, a second wiring layer 5, and a third wiring layer 6), a plurality of connection conductors 7 that each connect the corresponding wiring layers to each other, and a plurality of wiring layer fixing members 9.

In the embodiment, as an example of the present disclosure, the wiring board 1 is described as one having a multi-layer structure including two insulating layers and three wiring layers. However, the number of insulating layers and the number of wiring layers in the wiring board of the present disclosure are not limited thereto.

Due to the design of a pattern of the wiring layers, the wiring board 1 is used in, for example, a transformer, an insulated gate bipolar transistor (IGBT), a light emitting diode (LED) illumination device, a power transistor, or a motor. The wiring board I is particularly suitable for use in high-voltage and large-current applications.

Insulating Layers

The first insulating layer 2 and the second insulating layer 3 each have a front surface and a back surface. The main constituent of each of the first insulating layer 2 and the second insulating layer 3 is ceramic. Since ceramic has a high insulating property, it is suitable for use in large-current applications. The term “main constituent” means a constituent that is contained by 80 mass % or greater.

Examples of ceramic of which the first insulating layer 2 and the second insulating layer 3 are made include alumina, beryllia, aluminum nitride, boron nitride, silicon nitride, silicon carbide, and LTCC (Low Temperature Co-fired Ceramic). Such ceramics may be singly used, or combinations of two or more types of such ceramics may be used.

The first wiring layer 4 that is adjacent to the first insulating layer 2 is disposed on a front surface side of the first insulating layer 2. The second wiring layer 5 that is adjacent to the first insulating layer 2 is disposed on a back surface side of the first insulating layer 2. The second insulating layer 3 is disposed on the front surface side of the first insulating layer 2 with the first wiring layer 4 interposed therebetween. The third wiring layer 6 that is adjacent to the second insulating layer 3 is disposed on a front surface side of the second insulating layer 3.

The first insulating layer 2 has at least one through hole 2A that extends through the first insulating layer 2 in a thickness direction. The second insulating layer 3 has at least one through hole 3A that extends through the second insulating layer 3 in the thickness direction. The through holes 2A and 3A are so-called via holes where vias that electrically connect the wiring layers to each other are formed. In the embodiment, the through hole 2A in the first insulating layer 2 and the through hole 3A in the second insulating layer 3 are provided in corresponding positions as viewed from the thickness direction of the insulating layers 2 and 3 (that is, in plan view), and have the same diameter.

Wiring Layers

The first wiring layer 4, the second wiring layer 5, and the third wiring layer 6 are electrically conductive, and each contain a metal as a main constituent. Examples of metal include copper, aluminum, silver, gold, platinum, nickel, titanium, chromium, molybdenum, tungsten, and alloys thereof. Among these metals, from the viewpoints of cost, electrical conductivity, thermal conductivity, and strength, copper is desirable. Therefore, a copper foil or a copper plate can be suitably used as each of the wiring layers 4, 5, and 6.

The first wiring layer 4 is disposed on the front surface side of the first insulating layer 2. The first wiring layer 4 includes fixing regions A1 and A2 that are fixed to the first insulating layer 2, and unfixing regions B that are not fixed to the first insulating layer 2.

The second wiring layer 5 is disposed on the back surface side of the first insulating layer 2. The third wiring layer 6 is disposed on the front surface side of the second insulating layer 3. Similarly to the first wiring layer 4, the second wiring layer 5 and the third wiring layer 6 each include fixing regions A1 and A2 that are fixed to the insulating layer corresponding thereto, and unfixing regions B that are not fixed to the insulating layer corresponding thereto. The details of the fixing regions A1 and A2 and the unfixing regions B are described later.

Connection Conductors

The plurality of connection conductors 7 are each disposed in a corresponding one of the through hole 2A in the first insulating layer 2 and the through hole 3A in the second insulating layer 3. The connection conductors 7 are so-called vias that each electrically connect the first wiring layer 4 to the second wiring layer 5 or to the third wiring layer 6. The connection conductors 7 each join the first wiring layer 4 to the second wiring layer 5 or to the third wiring layer 6.

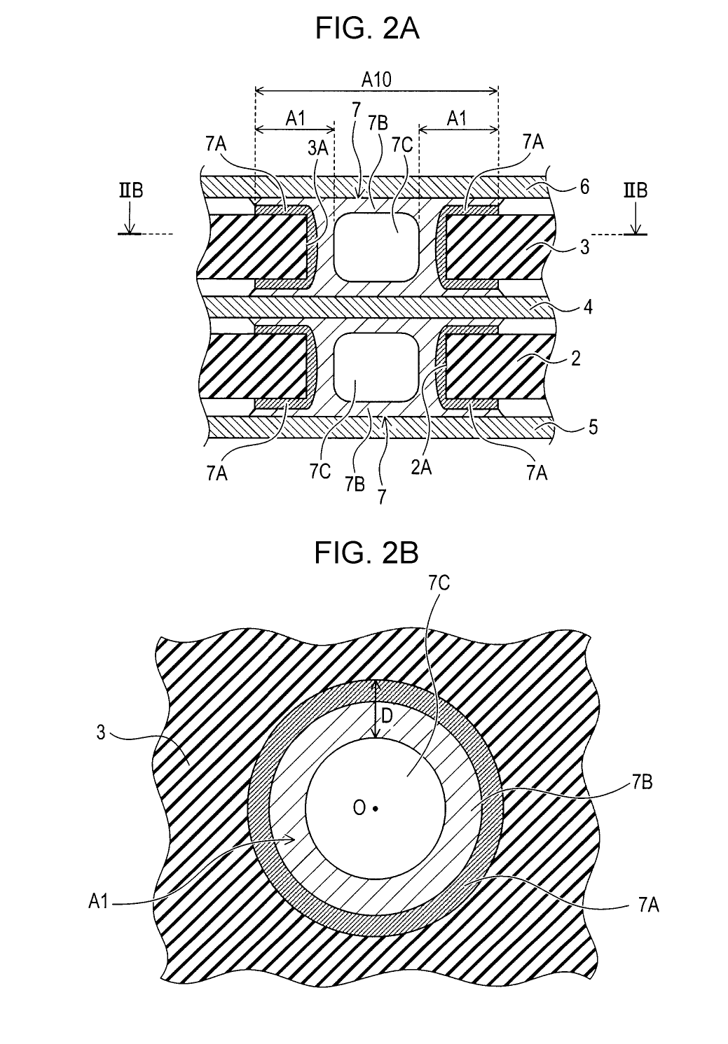

As shown in FIG. 2A, each connection conductor 7 includes a metallized layer 7A and a joining portion 7B. Although, in the description below, the connection conductor 7 that is disposed in the through hole 2A of the first insulating layer 2 is described, the description below similarly also applies to the connection conductor 7 that is disposed in the through hole 3A of the second insulating layer 3.

The metallized layer 7A includes inner walls of the first insulating layer 2 that form the through hole 2A and, of the front surface and the back surface of the first insulating layer 2, a peripheral region of the through hole 2A. The metallized layer 7A contains a metal as a main constituent. As the metal, the aforementioned metals that are usable in the wiring layers 4, 5, and 6 described above may be used.

The joining portion 7B is electrically conductive. The joining portion 7B is joined to the metallized layer 7A, the back surface of the first wiring layer 4 (that is, the surface facing the first insulating layer 2), and the front surface of the second wiring layer 5 (that is, the surface facing the first insulating layer 2). The joining portion 7B may be, for example, a metal brazing material, such as a silver-copper alloy, or a solder material, such as a tin-silver-copper alloy.

At a location surrounding the through hole 2A, the joining portion 7B is provided between the front surface of the first insulating layer 2 and the back surface of the first wiring layer 4 and between the back surface of the first insulating layer 2 and the front surface of the second wiring layer 5, and these are joined together. A hollow portion 7C, which has the form of a gap, is formed in the central portion of the joining portion 7B. The connection conductor 7 need not have the hollow portion 7C.

Wiring Layer Fixing Members

As shown in FIG. 1, the plurality of wiring layer fixing members 9 are each disposed between the first wiring layer 4 and the first insulating layer 2, between the first wiring layer 4 and the second insulating layer 3, between the second wiring layer 5 and the first insulating layer 2, or between the third wiring layer 6 and the second insulating layer 3.

For example, similarly to the joining portions 7B of the connection conductors 7, the plurality of wiring layer fixing members 9 are made of a metal brazing material or a solder material. The first wiring layer 4 is joined to the first insulating layer 2 and the second insulating layer 3 by the wiring layer fixing members 9 corresponding thereto. The wiring layer fixing members 9 and the insulating layers 2 and 3 can be easily fixed to each other when metallized layers (not shown) are formed in a range corresponding to auxiliary fixing regions A2 of the insulating layers 2 and 3.

Fixing Regions and Unfixing Regions

As described above, the plurality of wiring layers 4, 5, and 6 each include the fixing regions A1 and A2 and the unfixing regions B. In the embodiment, the fixing regions A1 and A2 and the unfixing regions B of the wiring layer 4, the fixing regions A1 and A2 and the unfixing regions B of the wiring layer 5, and the fixing regions A1 and A2 and the unfixing regions B of the wiring layer 6 are disposed at corresponding locations in plan view. Although in the description below, each region is described by using the first wiring layer 4, the following description also similarly applies to the other wiring layers.

The fixing regions A1 and A2 are a connection-portion fixing region A1 and a plurality of auxiliary fixing regions A2.

As shown in FIG. 2A, the connection-portion fixing region A1 is a region in which the peripheral region of the through hole 2A of the first insulating layer 2 and the first wiring layer 4 are fixed to each other in the thickness direction by the connection conductor 7.

At the connection-portion fixing region A1, the first insulating layer 2, the metallized layer 7A, the Mining portion 7B, and the first wiring layer 4 are laminated to each other in that order. As shown in FIG. 2B, in plan view, the connection-portion fixing region A1 is, of a region where the first wiring layer 4 and the joining portion 7B overlap each other, a region excluding a region overlapping the hollow portion 7C. When the hollow portion 7C does not exist (including, for example, a case in which a metal member is disposed in the joining portion 7B), the connection-portion fixing region becomes an illustrated region denoted by “A10” in FIG. 2A. As shown in FIG. 1, the region on the inner side of the through hole 2A is included in the unfixing region B.

Each auxiliary fixing region A2 is a region other than the connection-portion fixing region A1 and where the first wiring layer 4 is fixed to the first insulating layer 2. More specifically, as shown in FIG. 1, the first wiring layer 4, the regions where the wiring layer fixing members 9 are joined form the auxiliary fixing regions A2. The planar shape of each auxiliary fixing region A2 is not particularly limited to certain shapes. Regions where the wiring layer fixing members 9 are not joined are included in the unfixing regions B.

The maximum distance from the gravity center of the connection-portion fixing region A1 and from the gravity center of each auxiliary fixing region A2 to an outer edge as viewed from the thickness direction of the first wiring layer 4 is desirably 7 mm or less and more desirably 5 mm or less. When the maximum distance is too large, cracks and breakages caused by differences between the thermal expansion coefficient of the insulating layers and thermal expansion coefficient of the wiring layers may occur in the first insulating layer 2 and the second insulating layer 3.

The expression “the maximum distance from the gravity center of a fixing region to an outer edge of the fixing region” refers to, of the lengths of line segments extending from the gravity center of the fixing region to the outer edge of the fixing region (may also be called “extended line segments” below), the length of the longest extended line segment. When an unfixing region is included within the fixing region (for example, when the fixing region has a ring shape), first, a virtual gravity center including the unfixing region included in the fixing region is determined, and the extended line segment is acquired. Next, of the length of the acquired extended line segment, the length of a portion passing through the unfixing region is excluded from the length. That is, the length of the extended line segment corresponds to the length of only the portion included in the fixing region.

Therefore, as shown in FIG. 2B, in the case of the connection-portion fixing region A1, a maximum distance D from a gravity center O thereof to an outer edge thereof is the width of the metallized layer 7A (the difference between the outside diameter and the inside diameter in plan view).

In the unfixing regions B, in the embodiment, each of the wiring layers 4, 5, and 6 is disposed apart from the first insulating layer 2 or the second insulating layer 3. However, each of the wiring layers 4, 5, and 6 may contact the first insulating layer 2 or the second insulating layer 3. That is, in the unfixing regions B, as long as the wiring layers and the insulating layers are capable of being individually displaced in a planar direction, the wiring layers and the insulating layers need not be disposed apart from each other as they are in each figure, and may contact each other.

1-2. Method of Manufacturing Wiring Board

Next, a method of manufacturing the wiring board 1 is described.

The wiring board 1 is acquired by performing a manufacturing method including, for example, an insulating layer forming step, a joining material placing step, and a laminating step. Here, the wiring board 1 in which wiring layers are electrically connected to each other via through holes is described as an example.

Insulating Layer Forming Step

In this step, a plurality of insulating layers having through holes are formed.

In this step, first, unsintered ceramic is molded into the form of a ceramic substrate. More specifically, first, ceramic powder, an organic binder, a solvent, and a plasticizer or other additives are mixed with each other to acquire a slurry. Next, by molding the slurry into the form of a sheet by a publicly known method, the unsintered ceramic having the form of a substrate (a so-called ceramic green sheet) is acquired.

Through holes 2A and 3A are formed in the acquired ceramic green sheet. Thereafter, unsintered conductors, which become metallized layers 7A, are applied to the through holes 2A and 3A by printing. Each unsintered conductor is a paste formed by adding, for example, a solvent to a structural material of the corresponding metallized layer 7A.

After subjecting the unsintered conductors to printing, the ceramic green sheet is sintered. This forms ceramic insulating lavers 2 and 3. The unsintered conductors are sintered in the same step to form the metallized layers 7A. In order to increase the joinability with joining portions 7B, after the sintering, the metallized layers 7A may be, for example, plated with metallic coatings of, for example, nickel.

Joining Material Placing Step

In this step, joining materials for forming the joining portions 7B are placed in the through holes 2A and 3A. More specifically, the joining materials, which are metal brazing materials or solder materials, are placed in the through holes 2A and 3A to cause reflow by heating. This forms the joining portions 7B in the through holes 2A and 3A. For example, paste-like metal brazing materials or small pieces cut out from a preform, where, for example, metal brazing materials are previously molded, may be placed in the through holes 2A and 3A.

In this step, the reflow need not be performed. The reflow of the joining materials may be performed by heating in the next laminating step. However, from the viewpoint of increasing the reliability of connection of the joining portions 7B, it is desirable to perform the reflow before the laminating step.

Laminating Step

With a plurality of wiring layer fixing members 9 each being disposed between the insulating layer and the wiring layer corresponding thereto while the plurality of insulating layers 2 and 3, where the joining materials are placed in the through holes 2A and 3A, and the plurality of wiring layers 4, 5, and 6 being alternately placed one above the other in the thickness direction, a multilayer body is heated. This joins the insulating layer 2 to the wiring layer 4 and the wiring layer 5 by the corresponding connection conductor 7 and the corresponding wiring layer fixing members 9, and the insulating layer 3 to the wiring layer 4 and the wiring layer 6 by the corresponding connection conductor 7 and the corresponding wiring-layer fixing members 9.

1-3. Effects

The embodiment described in detail above provides the following effects.

(1a) When the wiring layers 4, 5, and 6 and the insulating layers 2 and 3 have expanded or contracted due to changes in temperature, the difference between the deformation amount of each of the wiring layers 4, 5, and 6 and the deformation amount of each of the insulating layers 2 and 3 caused by differences between the thermal expansion coefficient of each of the wiring layers 4, 5, and 6 and the thermal expansion coefficient of each of the insulating layers 2 and 3 can be absorbed by the unfixing regions B that are not fixed to the insulating layer 2 or the insulating layer 3. Therefore, stress that is generated between the insulating layer 2 and the wiring layer 4, between the insulating layer 2 and the wiring layer 5, between the insulating layer 3 and the wiring layer 4, and between the insulating layer 3 and the wiring layer 6 is reduced, and defects, such as cracks or breakages, in the insulating layers 2 and 3 are suppressed.

Therefore, for example, in order to cause a relatively large current to flow, even if the wiring layers 4, 5, and 6 are coil patterns having a relatively large area, breakage of the insulating layers 2 and 3 caused by changes in temperature is suppressed. As a result, it is possible to provide a high-quality transformer that deals with a high voltage and a large current.

For example, it is possible to use alumina (having a thermal expansion coefficient of 7.6×10⁻⁶ m/K) as the main constituent of each insulating layer, and use copper (having a thermal expansion coefficient of 17×10⁻⁶ m/K) as the main constituent of each wiring layer. Since alumina has a high voltage resistance, it is desirable to use alumina for the insulating layers. Since copper has a low resistivity, it is desirable to use copper for the wiring layers.

(1b) The first wiring layer 4, the second wiring layer 5, and the third wiring layer 6 each include the connection-portion fixing region A1, and are fixed to the first insulating layer 2 or the second insulating layer 3 by the corresponding connection conductor 7 with a relatively small area. As a result, it is possible to hold each of the wiring layers 4, 5, and 6 with respect to the insulating layer 2 or the insulating layer 3 while suppressing the generation of stress caused by differences between the thermal expansion coefficients.

(1c) Since the first wiring layer 4, the second wiring layer 5, and the third wiring layer 6 each include the auxiliary fixing regions A2, it is possible to more stably hold the wiring layers 4, 5, and 6 while suppressing the generation of stress caused by differences between the thermal expansion coefficients.

2. Second Embodiment

2-1. Wiring Board

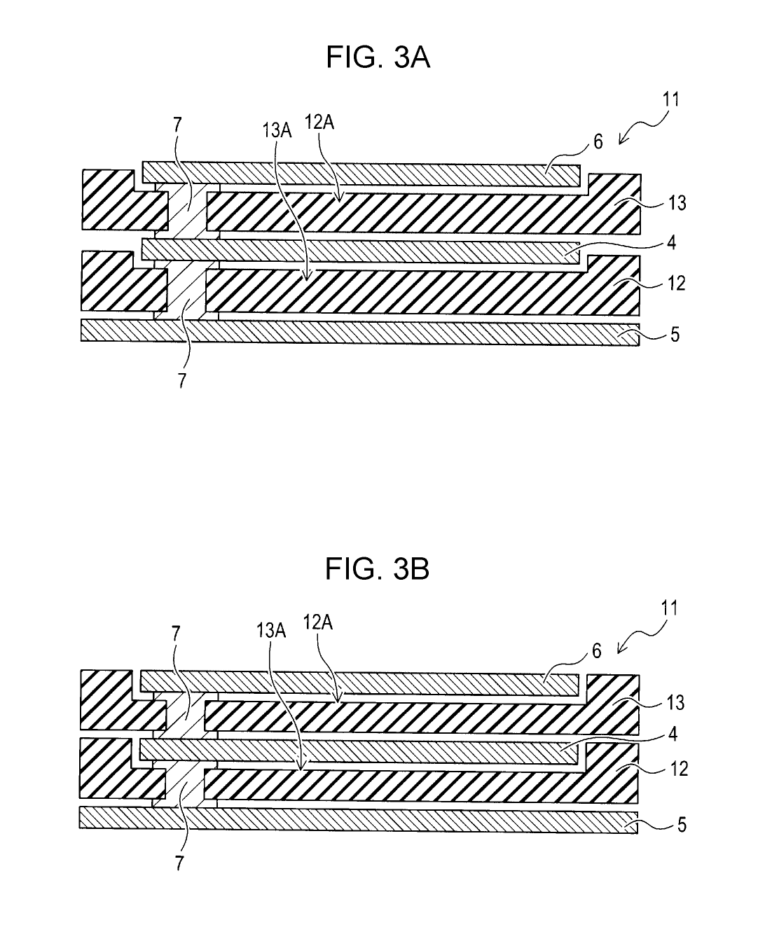

A wiring board 11 shown in FIG. 3A includes a plurality of insulating layers (a first insulating layer 12 and a second insulating layer 13), a plurality of wiring layers (a first wiring layer 4, a second wiring layer 5, and a third wiring layer 6), and a plurality of connection conductors 7 that each connect the corresponding wiring layers. Since the plurality of wiring layers 4, 5, and 6 and the plurality of connection conductors 7 are similar to those of the wiring board 1 of FIG. 1, they are given the same reference numerals and are not described.

Insulating Layers

The first insulating layer 12 differs from the first insulating layer 2 of FIG. 1 in that it includes in its surface a grooved portion 12A that is thinner than other portions of the first insulating layer 12. The second insulating layer 13 differs from the second insulating layer 3 of FIG. 1 in that it includes in its surface a grooved portion 13A that is thinner than the other portions of the second insulating layer 13.

The grooved portion 12A is formed such that the first wiring layer 4 is capable of being disposed therein. The grooved portion 13A is formed such that the third wiring layer 6 is capable of being disposed therein. At least a part of the first wiring layer 4 in a thickness direction is disposed in the grooved portion 12A of the first insulating layer 12. At least a part of the third wiring layer 6 in the thickness direction disposed in the grooved portion 13A of the second insulating layer 13.

More specifically, the planar shape (the outer edge) of the grooved portion 12A is similar to the planar shape of the first wiring layer 4, and is slightly larger than the first wiring layer 4. The planar shape (the outer edge) of the grooved portion 13A is similar to the planar shape (the outer edge) of the third wiring layer 6, and is slightly larger than the third wiring layer 6. That is, by an inner wall of the first insulating layer 12 that forms the grooved portion 12A of the first insulating layer 12, the first wiring layer 4 is surrounded; and by an inner wall of the second insulating layer 13 that forms the grooved portion 13A in the second insulating layer 13, the third wiring layer 6 is surrounded. That is, when the first wiring layer 4 is disposed in the grooved portion 12A, or the third wiring layer 6 is disposed in the grooved portion 13A, a gap is formed between the wiring layer and the inner wall of the corresponding insulating layer that forms the grooved portion.

The depths of the grooved portions 12A and 13A are not particularly limited to certain depths. The depth of the grooved portion 12A and the depth of the grooved portion 13A may be smaller than the thickness of the wiring layer 4 and the thickness of the wiring layer 6, respectively, as shown in FIG. 3A; or may be larger than the thickness of wiring layer 4 and the thickness of the wiring layer 6, respectively. From the viewpoint of reducing the height of the wiring board 1, as shown in FIG. 3B, as shown in FIG. 3B, the depth of the grooved portion 12A and the depth of the grooved portion 13A may equal the thickness of wiring layer 4 and the thickness of the wiring layer 6, respectively. That is, surfaces of regions of the insulating layers 12 and 13 other than the grooved portions 12A and 13A corresponding thereto may be flush with the surfaces of the corresponding wiring layers 4 and 6.

2-2. Effects

The embodiment described in detail above provides the following effects.

(2a) While suppressing the generation of stress caused by differences between the thermal expansion coefficients of the insulating layers 12 and 13 and the thermal expansion coefficients of the wiring layers 4, 5, and 6, it is possible to reduce the thickness of the wiring board 1 by the grooved portions 12A and 12B. Further, since it is possible to reduce the lengths of the connection conductors 7 that extend through the corresponding insulating layers 12 and 13, it is possible to reduce resistance.

3. Third Embodiment

3-1. Wiring Board

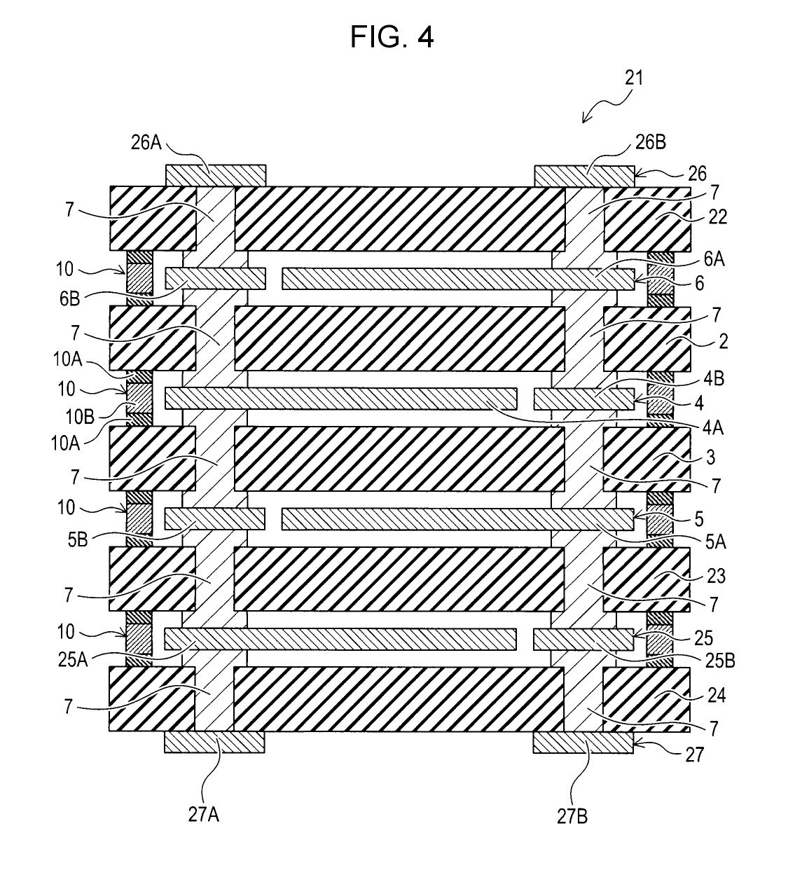

A wiring board 21 shown in FIG. 4 includes a plurality of insulating layers (a first insulating layer 2, a second insulating layer 3, a third insulating layer 22, a fourth insulating layer 23, and a fifth insulating layer 24), a plurality of wiring layers (a first wiring layer 4, a second wiring layer 5, a third wiring layer 6, a fourth wiring layer 25, a fifth wiring layer 26, and a sixth wiring layer 27), a plurality of connection conductors 7 that each connect the corresponding wiring layers, and a plurality of insulating layer fixing members 10.

Since the plurality of insulating layers 2 and 3, the wiring layers 4, 5, and 6, and the plurality of connection conductors 7 are similar to those of the wiring board I in FIG. 1, they are given the same reference numerals and are not described.

The third insulating layer 22, the fourth insulating layer 23, and the fifth insulating layer 24 have the same structure as the first insulating layer 2. The third insulating layer 22 is disposed on a front surface side of the first insulating layer 2. The fourth insulating layer 23 and the fifth insulating layer 24 are disposed on a back surface side of the second insulating layer 3 in this order.

Wiring Layers

The fourth wiring layer 25 is disposed between the fourth insulating layer 23 and the fifth insulating layer 24. The fifth wiring layer 26 is disposed on a front surface side of the third insulating layer 22. The sixth wiring layer 27 is disposed on a back surface side of the fifth insulating layer 24.

The fifth wiring layer 26 includes terminals 26A and 26B that are electrically connected to the outside. The sixth wiring layer 27 includes terminals 27A and 27B that are electrically connected to the outside. Each of the terminals 26A, 265, 27A, and 27B is shown as being joined to its corresponding insulating layer in its entirety. Since the terminals 26A, 265, 27A, and 27B have relatively small areas, and stress that is generated due to differences between the thermal expansion coefficients is small even if each of the terminals 26A, 265, 27A, and 275 is joined to its corresponding insulating layer in its entirety, each of the terminals 26A, 26B, 27A, and 275 may be joined to its corresponding insulating layer. However, since each of the terminals 26A, 265, 27A, and 275 only needs to be connected to its corresponding wiring layer by its corresponding connection conductor 7, for the reason that it is no longer necessary to consider the stress that is generated due to differences between the thermal expansion coefficients, it is desirable that each of the terminals 26A, 265, 27A, and 275 not be fixed to its corresponding insulating layer. Each of the terminals 26A, 265, 27A, and 275 may be fixed to its corresponding insulating layer only at its corresponding connection-portion fixing region A1 shown in FIG. 1 for the thermal expansion coefficients.

In the embodiment, the first wiring layer 4 includes a main wiring layer 4A and an auxiliary wiring layer 4B that is separated from the main wiring layer 4A; the second wiring layer 5 includes a main wiring layer 5A and an auxiliary wiring layer 5B that is separated from the main wiring layer 5A; the third wiring layer 6 includes a main wiring layer 6A and an auxiliary wiring layer 6B that is separated from the main wiring layer 6A; and the fourth wiring layer 25 includes a main wiring layer 25A and an auxiliary wiring layer 25B that is separated from the main wiring layer 25A.

The main wiring layers 4A, 5A, 6A, and 25A are each a wiring layer of a wiring pattern of, for example, a coil. Since each of the main wiring layers 4A, 5A, 6A, and 25A has a relatively large area, they each include unfixing regions B shown in FIG. 1.

The auxiliary wiring layers 4B, 5B, 6B, and 25B are each a wiring layer for connecting corresponding main wiring layers to each other in a thickness direction. For example, the auxiliary wiring layer 4B of the first wiring layer connects the main wiring layer 5A of the second wiring layer 5 and the main wiring layer 6A of the third wiring layer 6 to each other via the connection conductor 7.

Similarly to the terminals 26A, 26B, 27A, and 27B, the auxiliary wiring layers 4B, 5B, 6B, and 25B each have a relatively small area, with a maximum distance from its gravity center to its outer edge in plan view being 7 mm or less. Therefore, each of the auxiliary wiring layers 4B, 5B, 6B, and 25B may be joined in its entirety to an insulating layer on a front surface side or on a back surface side in plan view without including unfixing regions B. In this case, each of the auxiliary wiring layers 4B, 5B, 6B, and 25B includes only a connection-portion fixing region A1 or auxiliary fixing regions A2. Each auxiliary wiring layer may be formed from the aforementioned copper foil or copper plate, or may be formed of the same material as the metallized layers 7A.

Insulating Layer Fixing Members

The insulating layer fixing members 10 are members that join adjacent insulating layers (for example, the first insulating layer 2 and the second insulating layer 3) to each other in the thickness direction Each insulating layer fixing member 10 is disposed between corresponding insulating layers. Each insulating layer fixing member 10 is disposed so as to surround a corresponding one of the first wiring layer 4, the second wiring layer 5, the third wiring layer 6, and the fourth wiring layer 25 as viewed from the thickness direction.

Each insulating layer fixing member 10 includes two metallized layers 10A and a joining portion 10B.

The two metallized layers 10A are disposed between a back surface of one of two insulating layers that are joined to each other (for example, a back surface of the first insulating layer 2) and a front surface of the other insulating layer (for example, a front surface of the second insulating layer 3).

Each joining portion 10B is disposed between the two metallized lavers 10A, and connects the two metallized layers 10A to each other in the thickness direction.

The material of each metallized layer 10A may contain, for example, tungsten or molybdenum as a main constituent. The material of each joining portion 10B may be the same as the material of the joining portion 7B of each connection conductor 7.

The plurality of insulating layer fixing members 10 may include insulating layer fixing members 10 that are formed from a resin adhesive, such as an epoxy resin adhesive or a silicone resin adhesive. Each insulating layer fixing member 10 may be formed by using a paste containing ceramic. When resin or ceramic is used, the metallized layers 10A need not be formed.

In order to seal and fix portions between the insulating layers, in addition to providing the insulating layer fixing members 10 that are provided between corresponding insulating layers, an insulating layer fixing member 10 that covers all at once a side portion of the wiring board over the plurality of insulating layers may be provided. Alternatively, instead of disposing each insulating layer fixing member 10 between corresponding insulating layers, it is possible to provide only the insulating layer fixing member 10 that covers all at once a side portion of the wiring board over the plurality of insulating lavers.

3-2. Effects

The embodiment described in detail above provides the following effects.

(3a) Since each of the wiring layers 4, 5, 6, and 25 is sealed by its corresponding insulating layer fixing member 10, oxidation of the wiring layers 4, 5, 6, and 25 and short circuits between wiring layers caused by moisture in the air are suppressed. More specifically, it is possible to suppress the occurrence of surface discharge caused by the adherence of moisture. As a result, it is possible to increase the reliability of the wiring board 1.

4. Other Embodiments

Although embodiments of the present disclosure are described above, the present disclosure is not limited to the above-described embodiments, and may obviously take various forms.

(4a) In the wiring board 1 of the above-described embodiments, each wiring layer fixing member 9 need not be provided between the corresponding wiring layer and the corresponding insulating layer. That is, each wiring layer may include only the connection-portion fixing region A1 without including the auxiliary fixing regions A2. When each wiring layer fixing member 9 is provided, each wiring layer fixing member 9 may be adhered to the corresponding insulating layer by using an adhesive at the auxiliary fixing regions A2. As the adhesive, a resin adhesive, such as an epoxy resin adhesive or a silicone resin adhesive, may be selected.

(4b) In the wiring board 1 of the above-described embodiments, each wiring layer need not include the connection-portion fixing region A1 and the auxiliary fixing regions A2. That is, each wiring layer may only include the unfixing regions B and need not be fixed to an insulating layer at all.

In this case, each connection conductor 7 does not include the metallized layer 7A provided at the insulating layer, and only includes the joining portion 7B. The joining portion 7B of each connection conductor 7 may be separated from a corresponding one of the insulating layers and disposed in a corresponding one of the through hole 2A and the through hole 3A.

(4c) In the wiring board 1 of the above-described embodiments, the fixing regions A1 of the corresponding wiring layers, the fixing regions A2 of the corresponding wiring layers, and the unfixing regions B of the corresponding wiring layers may be disposed at locations that do not correspond with each other in plan view. Therefore, the through holes of the corresponding insulating layers may also be disposed at locations that do not correspond with each other in plan view.

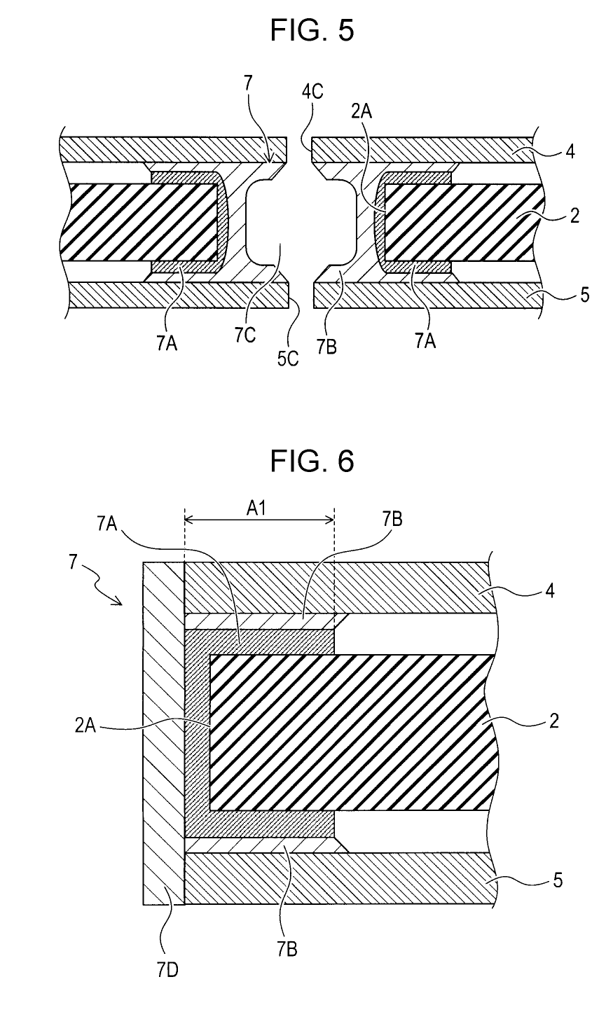

(4d) In the wiring board 1 of the above-described embodiments, as shown in FIG. 5, the first wiring layer may include an auxiliary through hole 4C at a location overlapping the through hole 2A of the first insulating layer 2 as viewed from the thickness direction, and the second wiring layer 5 may include an auxiliary through hole 5C at a location overlapping the through hole 2A of the first insulating layer 2 as viewed from the thickness direction.

By providing the auxiliary through holes 4C and 5C in this way, gas that is generated when forming the connection conductors 7 can be discharged to the outside of the through hole 2A (that is, degassing can be performed). As a result, it is possible to suppress bulging of the first wiring layer 4 and the second wiring layer 5. The auxiliary through hole 4C absorbs the thermal expansion of the first wiring layer 4, and the auxiliary through hole 5C absorbs the thermal expansion of the second wiring layer 5. Therefore, it is possible to reduce stress that is exerted upon the first insulating layer 2 and to suppress breakage of the first insulating layer 2.

When each wiring layer has such an auxiliary through hole, and the auxiliary through holes of the corresponding insulating layers are made to communicate with each other in the thickness direction, it is possible to discharge gas that is generated when forming the connection conductors 7 disposed on the inner side in the thickness direction.

(4e) In the wiring board 1 of each of the above-described embodiments, the metallized layer 7A of each connection conductor 7 need not be disposed on the entire surface of the inner wall of the insulating layer 2 in which the through hole 2A of the insulating layer 2 is formed or the entire surface of the inner wall of the insulating layer 3 in which the through hole 3A of the insulating layer 3 is formed. Each metallized layer 7A may be disposed on a part of the inner wall of the insulating layer 2 or a part of the inner wall of the insulating layer 3, or may be disposed on only the front surface or the back surface of the insulating layer 2 or on only the front surface or the back surface of the insulating layer 3.

Each connection conductor 7 that is disposed in a corresponding one of the through hole 2A and the through hole 3A may include a hollow portion 7C shown in FIG. 2A. That is, each connection conductor 7 may be in the form of a conformal via where the Mining portion 7B is formed along the inner wall of the insulating layer 2 having the through hole 2A or in the form of a conformal via where the joining portion 7B is formed along the inner wall of the insulating layer 3 having the through hole 3A. A portion of each hollow portion 7C shown in FIG. 2A may be in the form of a filled via, which is the joining portion 7B. Each connection conductor 7 may have a form in which a metal member is disposed in a corresponding one of the through hole 2A and the through hole 3A and the joining portion 7B is formed in the vicinity thereof.

(4f) In the wiring board 1 of each of the above-described embodiments, the insulating layer 2 need not include the through hole 2A, and the insulating layer 3 need not include the through hole 3A. That is, the connection conductors 7 need not be disposed in the through hole 2A or the through hole 3A.

For example, as shown in FIG. 6, a connection conductor 7 may be disposed on a side surface side of the insulating layer 2. In FIG. 6, the connection conductor 7 further includes a rod-shaped metal member 7D. The metallized layer 7A is disposed on the side surface and a part of the front surface and a part of the back surface of the insulating layer 2. The joining portion 7B may be disposed between the metallized layer 7A and the wiring layer 4 and between the metallized layer 7A and the wiring layer 5. The metal member 7D is joined to a side surface of the wiring layer 4, a side surface of the wiring layer 5, the metallized layer 7A, and the joining portion 7B.

In FIG. 6, the metallized layer 7A is disposed only on the inner wall of the insulating layer 2 that forms through hole 2A. Further, the connection conductor 7 need not be fixed to the insulating layer 2. That is, the connection conductor 7 may include only the metal member 7D that joins the wiring layers 4 and 5.

In FIG. 6, the connection conductor 7 need not include the metal member 7D. In this case, the metallized layer 7A is formed on the side surface and/or the front surface and the back surface of the insulating layer 2, and the wiring layers 4 and 5 are connected by the joining portion 7B. That is, the connection conductor 7 only includes the metallized layer 7A and the joining portion 7B.

As the joining portion 7B in FIG. 6, an adhesive may be used. That is, the wiring layers and the insulating layer may be fixed to each other by adhesion using an adhesive. In this case, a region where the adhesive is provided is included in the fixing region. As the joining portion 7B of each connection conductor 7 in FIGS. 1 to 6, a conductive adhesive may be used. That is, for example, in FIG. 1, the first wiring layer 4 and the second wiring layer 5 may be adhered to each other with a conductive adhesive.

(4g) In the wiring boards 1, 11, and 21 of the above-described embodiments, the material of each insulating layer is not limited to ceramic. For example, each insulating layer may contain, for example, a resin or glass as a main constituent.

(4h) The wiring boards 1, 11, and 21 of the above-described embodiments allow a planar transformer to be formed. That is, the first wiring layer and the second wiring layer may be such that a coil-like wiring pattern is provided at an outer edge portion of the insulating layer. Alternatively, a central portion of an insulating layer may have a core insertion hole that extends through an inner side of a wire-wound winding pattern having the form of a coil. For example, a magnetic-body core, such as a ferrite magnetic-body core, may be inserted into the core insertion hole.

(4i) Although, in the wiring boards 1, 11, and 21 of the above-described embodiments, the insulating layers are shown as having the same thickness and the wiring layers are shown as having the same thickness, the insulating layers may have different thicknesses and the wiring layers may have different thicknesses. The wiring layers may have different occupied areas.

In the wiring boards 1, 11, and 21 of the above-described embodiments, when unfixing regions where the insulating layers and the wiring layers are not fixed to each other exist, even if the thickness of the wiring layer on the front surface side of one insulating layer and the thickness of the wiring layer on the back surface side of the same insulating layer differ from each other, or the occupied areas of each of these wiring layers differ from each other, bending of the insulating layer is suppressed.

(4j) The function of one structural element in the above-described embodiments may be distributed among a plurality of structural elements, or the functions of a plurality of structural elements may be combined in one structural element. A part of the structure of an embodiment described above may be omitted. At least part of the structure of an embodiment described above may be, for example, added to or replaced by the structure of another embodiment described above. Various modes included in the technical idea that is specified from the wording in the scope of the claims correspond to embodiments of the present disclosure.

What is claimed is:

1. A wiring board comprising:
at least one insulating layer that has a front surface and a back surface;
a first wiring layer disposed adjacent to a front surface side of the at least one insulating layer;
a second wiring layer disposed adjacent to a back surface side of the at least one insulating layer; and
a connection conductor electrically connecting the first wiring layer to the second wiring layer,
wherein, of the first wiring layer and the second wiring layer, at least the first wiring layer includes an unfixing region that is not fixed to the at least one insulating layer.

2. The wiring board according to claim 1, wherein the first wiring layer includes at least one fixing region that is fixed to the at least one insulating layer, and
wherein the at least one fixing region includes a connection-portion fixing region that is fixed to the at least one insulating layer by the connection conductor.

3. The wiring board according to claim 2, wherein the at least one fixing region of the first wiring layer further includes an auxiliary fixing region where the first wiring layer is fixed to the at least one insulating layer at a location other than the connection-portion fixing region.

4. The wiring board according claim 2, wherein, as viewed from a thickness direction of the first wiring layer, a maximum distance from a gravity center of the at least one fixing region to an outer edge of the at least one fixing region is 7 mm or less.

5. The wiring board according to claim 1, wherein the at least one insulating layer includes a grooved portion that is thinner than other portions of the at least one insulating layer, and
wherein, in a thickness direction, at least a part of the first wiring layer is disposed in the grooved portion.

6. The wiring board according to claim 1, wherein the at least one insulating layer defines a through hole that extends through the at least one insulating layer in a thickness direction, and
wherein the connection conductor is disposed in the through hole.

7. The wiring board according to claim 1, wherein, at least one of the first wiring layer and the second wiring layer defines an auxiliary through hole at a location overlapping the through hole of the at least one insulating layer.

8. The wiring board according to claim 1, wherein the at least one insulating layer includes a first insulating layer and a second insulating layer, the first wiring layer disposed adjacent to a front surface side of the first insulating layer and the second wiring layer being disposed adjacent to a back surface side of the first insulating layer, the second insulating layer being disposed adjacent to the front surface side of the first insulating layer with the first wiring layer interposed between the first insulating layer and the second insulating layer,
wherein the wiring board further comprises an insulating layer fixing member that fixes the first insulating layer to the second insulating layer in a thickness direction, and
wherein, as viewed from a thickness direction of the first insulating layer, the insulating layer fixing member surrounds the first wiring layer.

9. A planar transformer using a wiring board including
at least one insulating layer that has a front surface and a back surface;
a first wiring layer disposed adjacent to a front surface side of the at least one insulating layer;
a second wiring layer disposed adjacent to a back surface side of the at least one insulating layer; and
a connection conductor electrically connecting the first wiring layer to the second wiring layer,
wherein, of the first wiring layer and the second wiring layer, at least the first wiring layer includes an unfixing region that is not fixed to the at least one insulating layer.
